(19) United States
(12) Patent Application Publication
(10) Pub. No.: US 2023/0240071 A1
(43) Pub. Date: Jul. 27, 2023

(54) THREE-DIMENSIONAL MEMORY DEVICE AND METHOD OF FORMING THE SAME

(71) Applicant: MACRONIX International Co., Ltd., Hsinchu (TW)

(72) Inventor: Pi-Shan Tseng, Hsing-Chu (TW)

(73) Assignee: MACRONIX International Co., Ltd., Hsinchu (TW)

(21) Appl. No.: 17/585,150

(22) Filed: Jan. 26, 2022

(51) Int. Cl. H01L 27/11582; H01L 27/11556; H01L 27/11519; H01L 27/11524; H01L 27/11565; H01L 27/1157

(52) U.S. Cl. CPC H01L 27/11582; H01L 27/11556; H01L 27/11519; H01L 27/11524; H01L 27/11565; H01L 27/1157

(57) ABSTRACT

Provided is a three-dimensional (3D) memory device including: a substrate, a stack structure, and a plurality of barrier structures. The stack structure is disposed on the substrate. The stack structure includes a plurality of dielectric layers and a plurality of gate layers stacked alternately. The plurality of barrier structures respectively wrap surfaces of the plurality of gate layers. Each barrier structure includes a first barrier layer and a second barrier layer. The first barrier layer continuously covers a top surface, a bottom surface and a first sidewall of a corresponding gate layer. The second barrier layer covers a second sidewall of the corresponding gate layer opposite to the first sidewall, and connects the first barrier layer. The second barrier layer has a thickness greater than a thickness of the first barrier layer. A method of forming a 3D memory device is also provided.

### BACKGROUND OF THE INVENTION

### Field of the Invention

The present invention relates to a semiconductor device and a method of forming the same, and more particularly to a three-dimensional (3D) memory device and a method of forming the same.

### Description of Related Art

A non-volatile memory (such as a flash memory) is a memory widely used in personal computers and other electronic devices because it has an advantage that the stored data does not disappear after being powered off.

The 3D flash memory currently used in the industry includes a NOR flash memory and a NAND type flash memory. In addition, another type of 3D flash memory is an AND type flash memory, which can be applied to a multi-dimensional flash memory array with high integration and high area utilization, and has an advantage of fast operation speed. Therefore, the development of the 3D flash memory has gradually become the current trend.

### SUMMARY OF THE INVENTION

The invention provides a three-dimensional (3D) memory device that uses a barrier structure to completely wrap all surfaces of the gate layer to prevent the fluorine outgassing issue, thereby improving the reliability of the device.

The invention provides a three-dimensional (3D) memory device including: a substrate, a stack structure, and a plurality of barrier structures. The stack structure is disposed on the substrate. The stack structure includes a plurality of dielectric layers and a plurality of gate layers stacked alternately. The plurality of barrier structures respectively wrap surfaces of the plurality of gate layers. Each barrier structure includes a first barrier layer and a second barrier layer. The first barrier layer continuously covers a top surface, a bottom surface and a first sidewall of a corresponding gate layer. The second barrier layer covers a second sidewall of the corresponding gate layer opposite to the first sidewall. The second barrier layer has a thickness greater than a thickness of the first barrier layer.

In an embodiment of the invention, the substrate includes an array region, and the array region includes a channel pillar region and a slit region.

In an embodiment of the invention, the 3D memory device further includes: a plurality of vertical channel pillars, penetrating through the stack structure and disposed on the channel pillar region and adjacent to the first sidewall; and a slit filling structure, penetrating through the stack structure and disposed on the slit region, and adjacent to the second sidewall, wherein the slit filling structure is physically separated from the corresponding gate layer by the second barrier layer.

In an embodiment of the invention, the slit filling structure includes: an oxide layer, covering a sidewall of the stack structure; a conductive layer, disposed on the oxide layer; and a third barrier layer, disposed between the oxide layer and the conductive layer.

In an embodiment of the invention, the second sidewall of the plurality of gate layers has a width less than a width of the plurality of the dielectric layers, so that the second sidewall and an adjacent dielectric layer jointly form a groove, and the oxide layer partially extends into the groove to connect the second barrier layer.

In an embodiment of the invention, the 3D memory device further includes: a buffer layer, conformally extending between the plurality of dielectric layers and the plurality of gate layers, and between the plurality of vertical channel pillars and the plurality of gate layers.

In an embodiment of the invention, the second barrier layer cover the second sidewall and a portion of an adjacent buffer layer, the second barrier layer and the buffer layer jointly form a recess, the recess has a first vertical depth and a second vertical depth, and the first vertical depth is greater than the second vertical depth.

In an embodiment of the invention, the first barrier layer is disposed between the buffer layer and the corresponding gate layer.

In an embodiment of the invention, each barrier structure completely wraps all surfaces of a corresponding gate layer.

In an embodiment of the invention, the 3D memory device includes: a 3D AND flash memory, a 3D NAND flash memory, a 3D NOR flash memory, or a combination thereof.

The invention provides a method of forming a three-dimensional (3D) memory device including: providing a substrate having a first region and a second region; forming a stack structure having a plurality of dielectric layers and a plurality of sacrificial layers alternately stacked on the substrate; forming a slit in the stack structure in the second region; performing a first etching process through the slit to remove the plurality of sacrificial layers to form a plurality of gaps between the plurality of dielectric layers; forming a plurality of gate layers and a plurality of first barrier layers in the plurality of gaps, wherein the plurality of first barrier layers surround a portion of a surface of the plurality of gate layers and expose a sidewall of the plurality of gate layers; and forming a plurality of second barrier layers to cover the sidewall of the plurality of gate layers, wherein the plurality of second barrier layers are respectively connected to the plurality of first barrier layers to form a plurality of barrier structures.

In an embodiment of the invention, after forming the plurality of second barrier layers, the method further includes forming a slit filling structure in the slit.

In an embodiment of the invention, before forming the slit, the method further includes forming a plurality of vertical channel pillars in the stack structure in the first region.

In an embodiment of the invention, the forming the plurality of gate layers and the plurality of first barrier layers in the plurality of gaps includes: forming a first barrier material layer and a conductive material layer to fill in the plurality of gaps; and performing a second etching process to remove the first barrier material layer and the conductive material layer on a sidewall of the plurality of dielectric layers to form the plurality of gate layers and the plurality of first barrier layers in the plurality of gaps.

In an embodiment of the invention, a material of the first barrier material layer includes titanium (Ti), titanium nitride (TiN), tantalum (Ta), tantalum nitride (TaN), or a combination thereof.

In an embodiment of the invention, after performing the second etching process, the sidewall of the plurality of gate layers is concave from the sidewall of the plurality of the dielectric layers to form a plurality of grooves.

In an embodiment of the invention, the forming the plurality of second barrier layers includes: forming a second barrier material layer to conformally cover the sidewall of the plurality of the dielectric layers and a surface of the plurality of grooves; and performing a third etching process to remove the second barrier material on the sidewall of the plurality of the dielectric layers to form the plurality of second barrier layers in the plurality of grooves, wherein each second barrier layer is formed into a C-shaped structure.

In an embodiment of the invention, the first barrier material layer and the second barrier material layer have the same material.

Based on the above, in the present invention, an additional barrier layer is used to cover the sidewall of the gate layer and is connected to the barrier layer surrounding the gate layer, thereby forming a barrier structure that completely wraps all surfaces of the gate layer. Therefore, the barrier structure of the present invention is able to effectively prevent the fluorine outgassing issue from occurring, thereby improving the reliability of the 3D memory device. Further, the forming steps of the barrier structure of the present invention are compatible with the fabrication of current 3D memory device, and can be applied to various 3D memory devices.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a 3D memory device according to an embodiment of the invention.

FIG. 1B is a schematic plan view of FIG. 1A.

FIG. 2A, FIG. 3A, and FIG. 4A are schematic cross-sectional views illustrating a vertical channel pillar according to various embodiments of the invention.

FIG. 2B, FIG. 3B, and FIG. 4B are schematic plan views of FIG. 2A, FIG. 3A, and FIG. 4A, respectively.

FIG. 5 to FIG. 11 are schematic cross-sectional views of a manufacturing process of a 3D memory device according to an embodiment of the invention.

FIG. 12A, FIG. 12B, and FIG. 12C are respectively a schematic perspective view, a schematic plan view, and a schematic circuit diagram of a 3D AND flash memory according to an embodiment of the present invention.

FIG. 13 is a schematic cross-sectional view of a 3D memory device according to alternative embodiments of the invention.

### DESCRIPTION OF THE EMBODIMENTS

The invention is more blanketly described with reference to the figures of the present embodiments. However, the invention can also be implemented in various different forms, and is not limited to the embodiments in the present specification. The thicknesses of the layers and regions in the figures are enlarged for clarity. The same or similar reference numerals represent the same or similar devices and are not repeated in the following paragraphs.

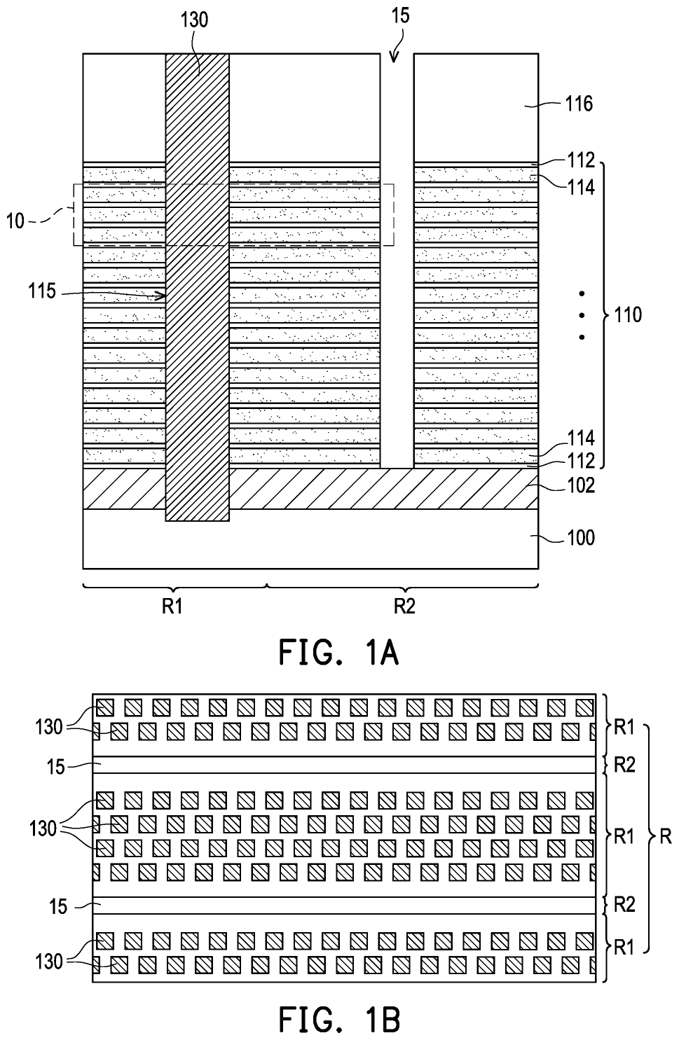

FIG. 1A is a schematic cross-sectional view of a 3D memory device according to an embodiments of the invention. FIG. 1B is a schematic plan view of FIG. 1A.

Referring to FIG. 1A and FIG. 1B, in the embodiment of the present invention, a 3D memory device may include a substrate 100, a stop layer 102, a stack structure 110, a cap layer 116, and a vertical channel pillar 130. In some embodiments, the substrate 100 is, for example, a semiconductor substrate, a semiconductor compound substrate, or a semiconductor over insulator (SOI) substrate. The semiconductor is, for example, an atom of group IVA, such as silicon or germanium. The semiconductor compound is, for example, a semiconductor compound formed by atoms of group IVA, such as silicon carbide or germanium silicide, or a semiconductor compound formed by atoms of group IIIA and group VA, such as gallium arsenide. In the embodiment, the substrate 100 may be a dielectric substrate. The dielectric substrate may be a dielectric layer formed on a silicon substrate, such as a silicon oxide layer. That is, there may be peripheral circuits under the substrate 100. In addition, the substrate 100 may include an array region R, the array region R may include a first region R1 and a second region R2. In an embodiment, the first region R1 may be a channel pillar region, and the second region R2 may be a slit region. That is, one or more slits may be adjacent to the channel pillar region R1, as shown in FIG. 1B.

The stop layer 102 may be formed on the substrate 100. In an embodiment, a material of the stop layer 102 includes a conductive material, such as polysilicon, III-V compound semiconductor, or a combination thereof. With an embodiment of the 3D memory device being a 3D NAND flash memory, the stop layer 102 may be used as a source line. With an embodiment of the 3D memory device being a 3D NOR flash memory, the stop layer 102 may be used as a dummy word line. Although the stop layer 102 illustrated in FIG. 1A is a single-layered structure, the present invention is not limited thereto. In other embodiments, the stop layer 102 may also be a multi-layered structure. The multilayer structure may include a plurality of dielectric layers (e.g., silicon oxide layers) and a plurality of conductive layers (e.g., polysilicon layers) stacked alternately.

The stack structure 110 may be formed on the stop layer 102, so that the stop layer 102 is disposed between the substrate 100 and the stack structure 110. In an embodiment, the stack structure 110 may include a plurality of dielectric layers 112 and a plurality of sacrificial layers 114 stacked alternately. In an embodiment, the dielectric layers 112 and the sacrificial layers 114 may be different dielectric materials or materials with different etching rates. For example, the dielectric layers 112 may be silicon oxide layers; and the sacrificial layers 114 may be silicon nitride layers, polysilicon layers or metal tungsten layers. The number of the dielectric layers 112 and the sacrificial layers 114 may be adjusted by the needs, the invention is not limited thereto.

The cap layer 116 may be formed on the stack structure 110, so that the stack structure 110 is disposed between the stop layer 102 and the cap layer 116. In an embodiment, a material of the cap layer 116 includes a dielectric material, such as silicon oxide.

The vertical channel pillar 130 may be formed in the stack structure 110 and the stop layer 102 in the first region R1. As shown in FIG. 1A, the vertical channel pillar 130 may penetrate through the stack structure 110, the stop layer 102, and partially extend into the substrate 100. It should be noted that when forming an opening 115 that may accommodate the vertical channel pillar 130, the stop layer 102 may be used not only as an etching stop layer, but also to prevent arcing effects generated during the plasma etching, thereby improving the reliability of the device. In this embodiment, the stop layer 102 may be regarded as a discharging layer, which is usually grounded to the silicon substrate to reduce the charge accumulated by the said plasma etching, thereby avoiding damage to the device. Therefore, during the high aspect ratio etching process, the stop layer 102 is usually grounded to the silicon substrate to avoid arc discharge.

Basically, according to different forms of the 3D memory device, the vertical channel pillar 130 may have different configurations, which are described in detail as follows.

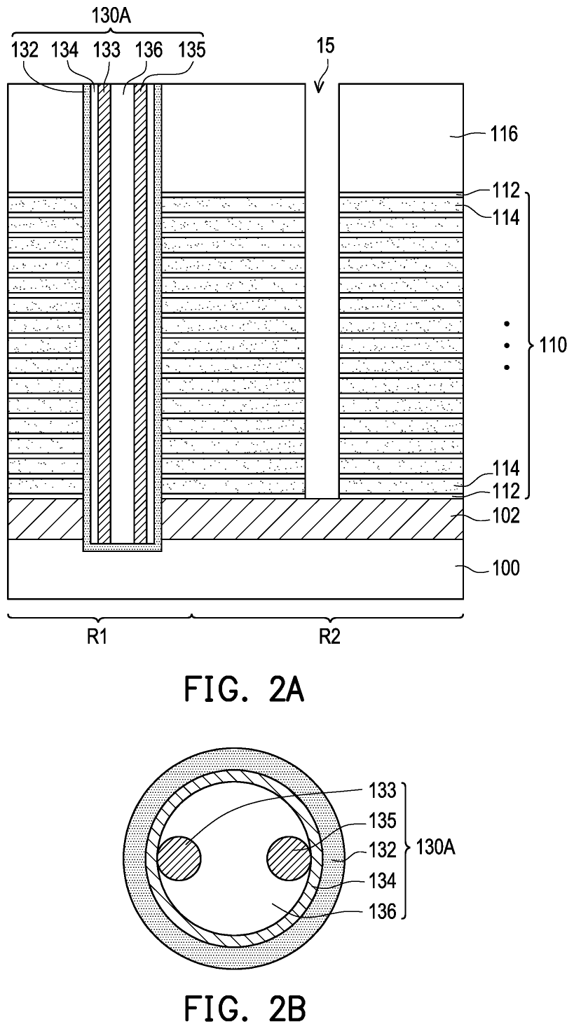

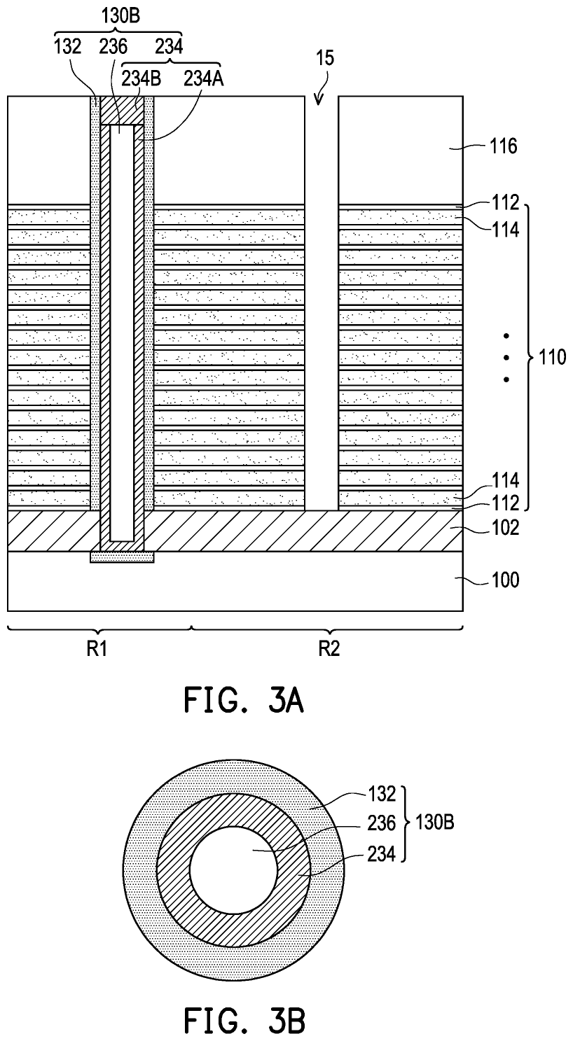

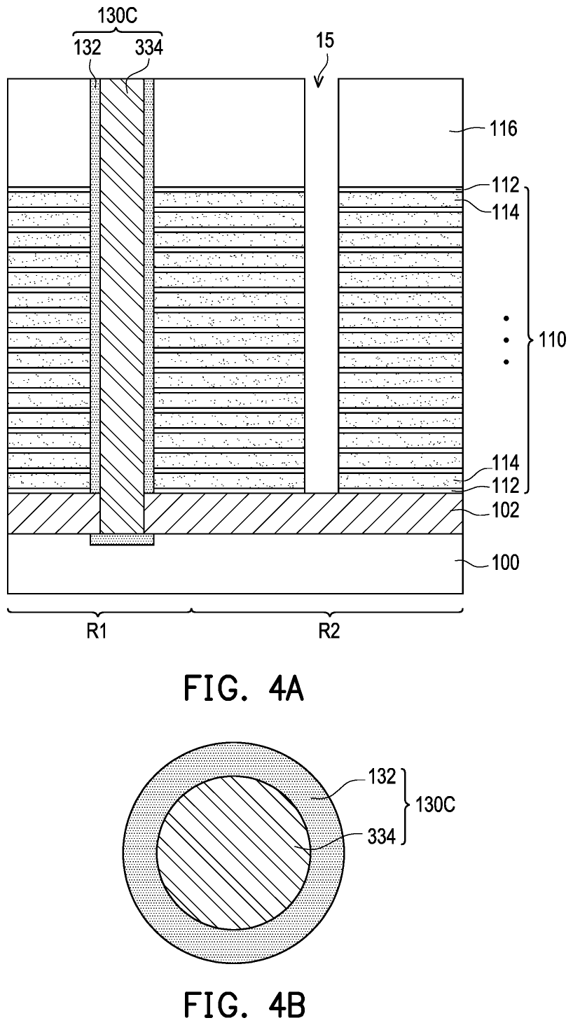

FIG. 2A, FIG. 3A, and FIG. 4A are schematic cross-sectional views illustrating a vertical channel pillar according to various embodiments of the invention. FIG. 2B, FIG. 3B, and FIG. 4B are schematic plan views of FIG. 2A, FIG. 3A, and FIG. 4A, respectively.

Referring to FIG. 2A and FIG. 2B, when the 3D memory device is a 3D AND flash memory, the vertical channel pillar 130A may include a charge storage structure 132, a channel layer 134, a dielectric material 136, a first source/drain (S/D) pillar 133, and a second S/D pillar 135. As shown in FIG. 2A, the first S/D pillar 133 and the second S/D pillar 135 may penetrate through the cap layer 116, the stack structure 110, and the stop layer 102, and partially extend into the substrate 100. In an embodiment, the first S/D pillar 133 and the second S/D pillar 135 may have the same conductive material, such as N-type doped (N+) polysilicon materials. The dielectric material 136 may disposed between the first S/D pillar 133 and the second S/D pillar 135 to separate the first S/D pillar 133 from the second S/D pillar 135. In addition, as shown in FIG. 2B, the channel layer 134 may laterally surround the dielectric material 136, the first S/D pillar 133 and the second S/D pillar 135. The first S/D pillar 133 and the second S/D pillar 135 physically contact a portion of the channel layer 134, respectively. The charge storage structure 132 may laterally surround the channel layer 134. In an embodiment, the charge storage structure 132 may be a composite layer of a tunneling layer, a charge storage layer and a block layer. The tunneling layer, the charge storage layer and the block layer may refer to oxide/nitride/oxide (ONO), respectively. In another embodiment, the tunneling layer may be a composite layer of oxide/nitride/oxide/(ONO), or other suitable materials. In alternative embodiments, the charge storage layer may be a composite layer of oxide/nitride/oxide (ONO), or other suitable materials. In other embodiments, the block layer may be a composite layer of oxide/nitride/oxide (ONO), or other suitable materials. The channel layer 134 may include a doped polysilicon layer or an undoped polysilicon layer. The dielectric material 136 may include silicon oxide, silicon nitride, silicon oxynitride, or a combination thereof.

Referring to FIG. 3A and FIG. 3B, when the 3D memory device is a first type of a 3D NAND flash memory, the vertical channel pillar 130B may include a charge storage structure 132, a channel structure 234, and a dielectric pillar 236. As shown in FIG. 3A, the dielectric pillar 236 may penetrate through the cap layer 116, the stack structure 110, and the stop layer 102. The channel structure 234 may include a liner 234A and a plug 234B. The liner 234A may cover the sidewall and the bottom surface of the dielectric pillar 236, and the plug 234B may seal the top surface of the dielectric pillar 236. In this case, the channel structure 234 may completely wrap all surfaces of the dielectric pillar 236. The charge storage structure 132 may be disposed between the channel structure 234 and the cap layer 116, and between the channel structure 234 and the stack structure 110. The charge storage structure 132 between the channel structure 234 and the stop layer 102 is removed, so that the channel structure 234 directly contacts the stop layer 102. From the perspective of the plan view of FIG. 3B, the charge storage structure 132 may laterally surround the channel structure 234 and the dielectric pillar 236. The materials of the charge storage structure 132, the channel structure 234 and the dielectric pillar 236 are respectively the same as the charge storage structure 132, the channel layer 134 and dielectric material 136, and have been described in detail in the foregoing paragraphs, thus will not be repeated here.

Referring to FIG. 4A and FIG. 4B, when the 3D memory device is a second type of a 3D NAND flash memory, the vertical channel pillar 130C may include a charge storage structure 132 and a channel pillar 334. As shown in FIG. 4A, the channel pillar 334 may penetrate through the cap layer 116, the stack structure 110, and the stop layer 102. The charge storage structure 132 may be disposed between the channel pillar 334 and the cap layer 116, between the channel pillar 334 and the stack structure 110. The charge storage structure 132 between the channel pillar 334 and the stop layer 102 is removed, so that the channel pillar 334 directly contacts the stop layer 102. From the perspective of the top view of FIG. 4B, the charge storage structure 132 may laterally surround the channel pillar 334. The materials of the charge storage structure 132 and the channel pillar 334 are respectively the same as the charge storage structure 132 and the channel layer 134, and have been described in detail in the foregoing paragraphs, thus will not be repeated here.

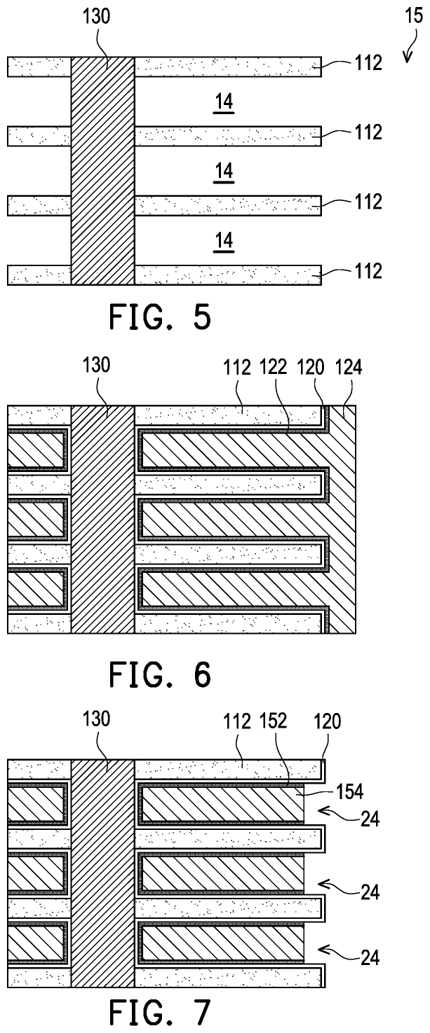

Referring back to FIG. 1A, after forming the vertical channel pillar 130, a gate replacement process may be performed to replace the sacrificial layers 114 in the stack structure 110 with gate layers 154, as shown in FIG. 5 to FIG. 11, wherein FIG. 5 to FIG. 11 are enlarged views of the region 10 illustrated in FIG. 1A. Specifically, first, as shown in FIG. 1A, a slit 15 is formed in the stack structure 110 in the second region R2. The slit 15 penetrates through the cap layer 116 and the stack structure 110 to expose a portion of the stop layer 102. Although the bottom surface of the slit 15 illustrated in FIG. 1A is flush with the top surface of the stop layer 102, the present invention is not limited thereto. In other embodiments, the bottom surface of the slit 15 may also be lower than the top surface of the stop layer 102. In addition, as shown in the plan view of FIG. 1B, the slit 15 may extend along the horizontal direction and is disposed between the vertical channel pillars 130 in two adjacent first regions R1. That is, the slit 15 may extend perpendicular to a paper orientation of FIG. 1A to form a trench.

Next, referring to FIG. 5, a first etching process is performed to remove the sacrificial layers 114 to form a plurality of gaps 14 between the dielectric layers 112. The gaps 14 laterally exposes the vertical channel pillars 130. In other words, the gap 14 is defined by the dielectric layer 112 and the vertical channel pillar 130. In one embodiment, the said first etching process may be a wet etching process. For example, when the sacrificial layers 114 are silicon nitride, the first etching process may use an etchant containing phosphoric acid and pour the etchant into the slit 15 to remove the sacrificial layers 114. Since the etchant has a high etching selectivity with respect to the sacrificial layers 114, the sacrificial layers 114 may be completely removed, while the dielectric layers 112 are not removed or is only slightly removed.

Referring to FIG. 5 and FIG. 6, a buffer layer 120, a barrier material layer 122, and a conductive material layer 124 are sequentially formed. Specifically, the buffer layer 120 and the barrier material layer 122 may conformally cover the surface of the structure shown in FIG. 5 and fill into the gaps 14; and the conductive material layer 124 may fill up the gaps 14 and extend laterally into the slit 15. In one embodiment, a material of the buffer layer 120 includes a high dielectric constant material with a dielectric constant greater than 7, such as aluminum oxide (Al₂O₃), hafnium oxide (HfO₂), lanthanum oxide (La₂O₅), transition metal oxide, lanthanide oxides or a combination thereof. A material of the barrier material layer 122 may include titanium (Ti), titanium nitride (TiN), tantalum (Ta), tantalum nitride (TaN), or a combination thereof. A material of the conductive material layer 124 may include polysilicon, amorphous silicon, tungsten (W), cobalt (Co), aluminum (Al), tungsten silicide (WSiₓ), or cobalt silicide (CoSiₓ).

Referring to FIG. 6 and FIG. 7, a second etching process is performed to remove the barrier material layer 122 and the conductive material layer 124 on the sidewalls of the dielectric layers 112 to form gate layers 154 and barrier layers 152 surrounding the gate layers 154 in the gaps 14. It should be noted that, in order to completely remove the conductive material layer 124 on the sidewalls of the dielectric layers 112 to form the gate layers 154 separated from each other, therefore, a portion of the conductive material layer 124 in the gaps 14 will be removed during the second etching process. In this case, as shown in FIG. 7, the sidewalls of the formed gate layers 154 are concaved from the sidewalls of the dielectric layers 112 to form a plurality of grooves 24. In one embodiment, the said second etching process may be a wet etching process, a dry etching process, or a combination thereof.

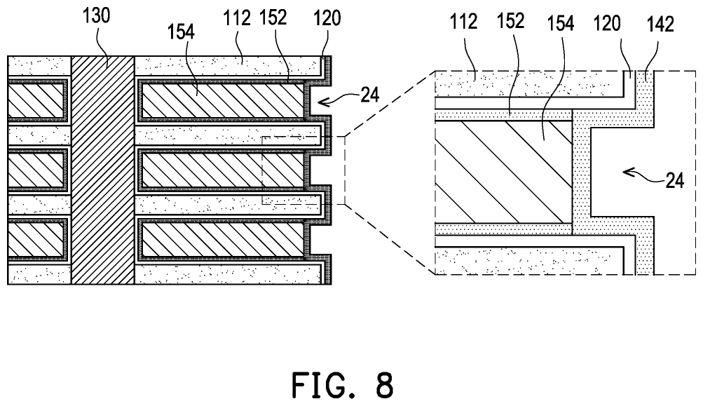

Referring to FIG. 8, a barrier material layer 142 is formed to conformally cover the surface of the buffer layer 120, the surface of the barrier layers 152, and the surface of the gate layers 154 (i.e., the surface of the grooves 24). In an embodiment, a material of the barrier material layer 142 may include titanium (Ti), titanium nitride (TiN), tantalum (Ta), tantalum nitride (TaN), or a combination thereof.

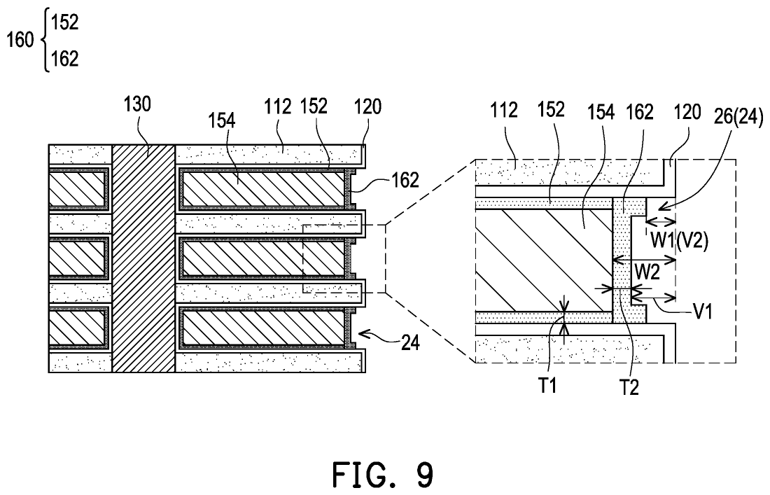

Referring to FIG. 8 and FIG. 9, a third etching process is performed to remove the barrier material layer 142 on the sidewalls of the dielectric layers 112 to form the barrier layers 162 in the grooves 24. In this case, as shown in FIG. 9, the barrier layer 152 and the barrier layer 162 may be connected to each other to form a barrier structure 160, and the barrier structure 160 completely wraps all surfaces of the gate layer 154. In some embodiments, the barrier layers 152 and 162 may have the same material, such as TiN. In alternative embodiments, the barrier layers 152 and 162 may have different materials. For example, the barrier layer 152 is a TiN layer, and the barrier layer 162 is a TaN layer.

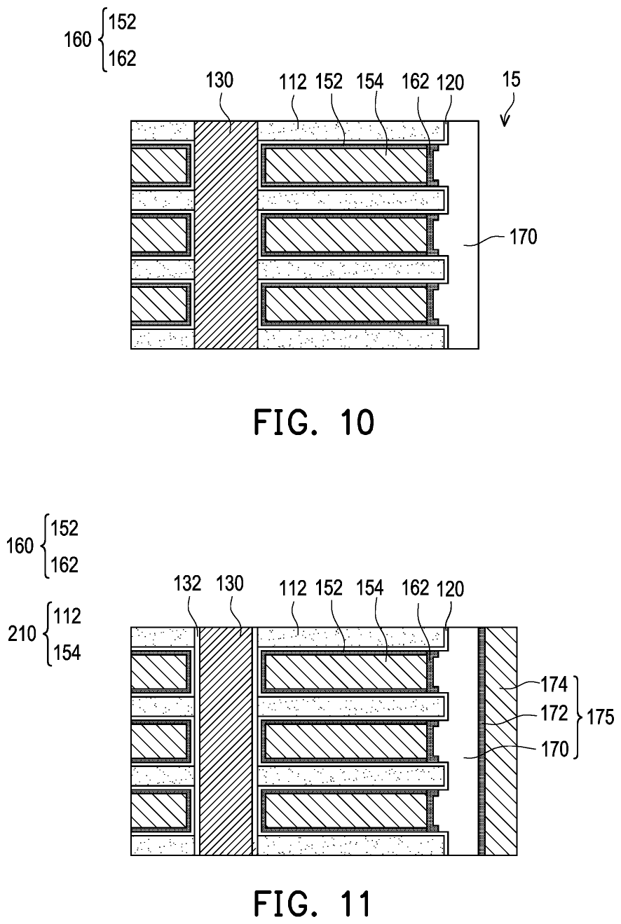

In an embodiment, a thickness T1 of the barrier layer 152 may be less than or equal to a thickness T2 of the barrier layer 162. The thickness T1 of the barrier layer 152 may be between 30 Å and 100 Å, and the thickness T2 of the barrier layer 162 may be between 50 Å and 150 Å. It should be noted that the thinner thickness T1 can make the barrier layers 152 easy to fill into the gaps 14 without affecting the formation of the subsequent gate layer 154. The thicker thickness T2 allows the barrier layers 162 to completely cover the sidewalls of the gate layers 154 to effectively prevent the fluorine outgassing issue from occurring. That is, if the barrier layers 162 are not formed on the sidewalls of the gate layers 154, the remaining fluorine in the gate layers 154 will escape and damage to-be-deposited oxide layer 170 (as shown in FIG. 10) on the sidewalls of the gate layers 154 during the subsequent heat treatment process, thereby generating voids. This results in the gate layers 154 are electrically connected (bridged) with the conductive layer 174 (as shown in FIG. 11) in the slit 15. Therefore, the barrier layer 162 of the present invention can effectively prevent the fluorine outgassing issue, thereby improving the reliability of the device.

In one embodiment, in order to completely remove the barrier material layer 142 on the sidewalls of the dielectric layers 112 to form the barrier layers 162 separated from each other, a portion of the barrier material layer 142 in the grooves 24 is removed during the third etching process. In this case, as shown in FIG. 9, the barrier layer 162 may form a C-shaped structure. Specifically, the barrier layer 162 covers the sidewall (i.e., the second sidewall) of the gate layer 154 and a portion of the adjacent buffer layer 120, so that the barrier layer 162 and the buffer layer 120 jointly form a recess 26. As shown in FIG. 9, the recess 26 has a first vertical depth V1 and a second vertical depth V2. In the embodiment, the first vertical depth V1 is greater than the second vertical depth V2. The first vertical depth V1 may be between 15 nm and 25 nm, and the second vertical depth V2 may be between 10 nm and 20 nm. In order to ensure that no barrier material remains on the sidewalls of the dielectric layers 112, the barrier material on the sidewalls of the gate layers 154 is further removed to avoid bridging between adjacent gate layers 154 (i.e., the bridge of word lines). Therefore, when the second vertical depth V2 is between 10 nm and 20 nm, it can be ensured that no barrier material remains on the sidewalls of the dielectric layers 112. On the other hand, in the embodiment, a width W1 between the outer sidewall of the barrier layer 162 and the sidewall of the buffer layer 120 may be between 10 nm and 20 nm, and a width W2 between the inner sidewall of the barrier layer 162 and the sidewall of the buffer layer 120 may be between 20 nm and 30 nm. However, the present invention is not limited thereto. In other embodiments, the barrier layer 162 may also form a linear structure.

Referring to FIG. 10, an oxide layer 170 is formed to cover the surfaces of the buffer layer 120 and the barrier layers 162 (i.e., the sidewall of the stack structure). Specifically, the oxide layer 170 may partially extend into the groove 24 of FIG. 9 to connect the barrier layer 162. In one embodiment, the oxide layer 170 may be formed by a low temperature oxidation process at a low temperature of 250° C. to 350° C. through a reaction gas, thereby forming the oxide layer 170 on the sidewall and the bottom of the slit 15. In this case, the oxide layer 170 may also be referred to as a low temperature oxide (LTO) layer. After forming the oxide layer 170, a heat treatment process may be performed to densify the oxide layer 170. In one embodiment, a temperature of the heat treatment process may range from 800° C. to 900° C., such as 850° C. In alternative embodiments, the oxide layer 170 may also be a high quality oxide (HQO) layer. It should be noted that, in the present invention, the barrier layers 162 can effectively block the remaining fluorine in the gate layers 154 from escaping due to the said heat treatment process, so as to prevent the oxide layer 170 from being damaged, thereby improving the reliability of the device.

Referring to FIG. 11, a barrier layer 172 and a conductive layer 174 are sequentially formed on the oxide layer 170, thereby forming a slit filling structure 175. In an embodiment, a material of the barrier layer 172 may include titanium (Ti), titanium nitride (TiN), tantalum (Ta), tantalum nitride (TaN), or a combination thereof. A material of the conductive layer 174 may include polysilicon, amorphous silicon, tungsten (W), or a combination thereof.

As shown in FIG. 11, in the present embodiment, the 3D memory device at least includes: the stack structure 210, the vertical channel pillar 130, the plurality of barrier structures 160, and the slit filling structure 175. The stack structure 210 includes the plurality of dielectric layers 112 and the plurality of gate layers 154 stacked alternately. The barrier structures 160 respectively wrap the surfaces of the gate layers 154. Each barrier structure 160 includes: a first barrier layer 152 and a second barrier layer 162. The first barrier layer 152 continuously covers a top surface, a bottom surface, and a first sidewall of the corresponding gate layer 154. The second barrier layer 162 covers a second sidewall of the corresponding gate layer 154 opposite to the first sidewall, and is connected to the first barrier layer 152. The slit filling structure 175 penetrates the stack structure 210. The second barrier layer 162 may physically separate the slit filling structure 175 and the gate layer 154, so as to effectively block the remaining fluorine in the gate layer 154 from escaping, and prevent the conductive layer 174 from bridging with the gate layer 154, thereby improving the reliability of the device.

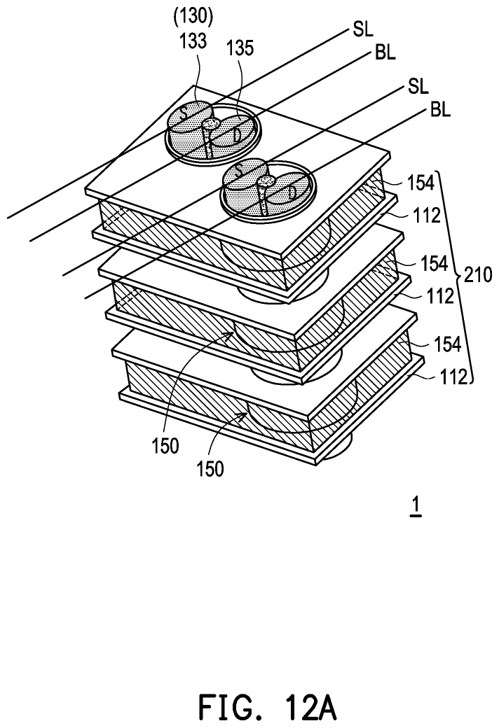

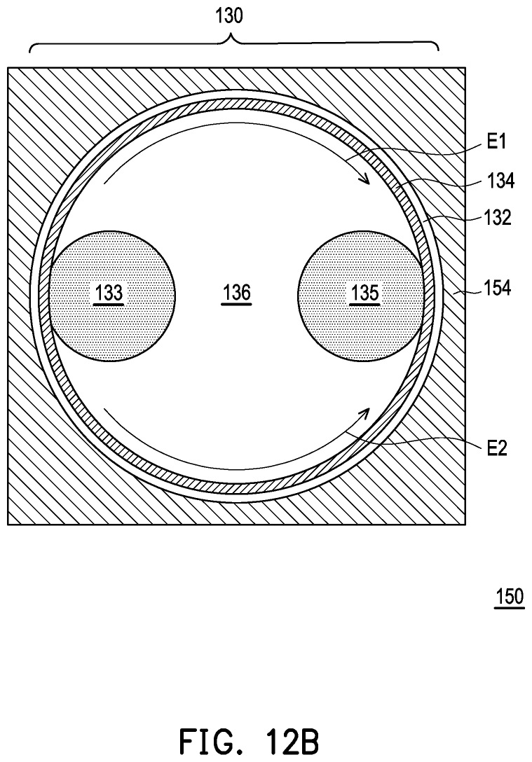

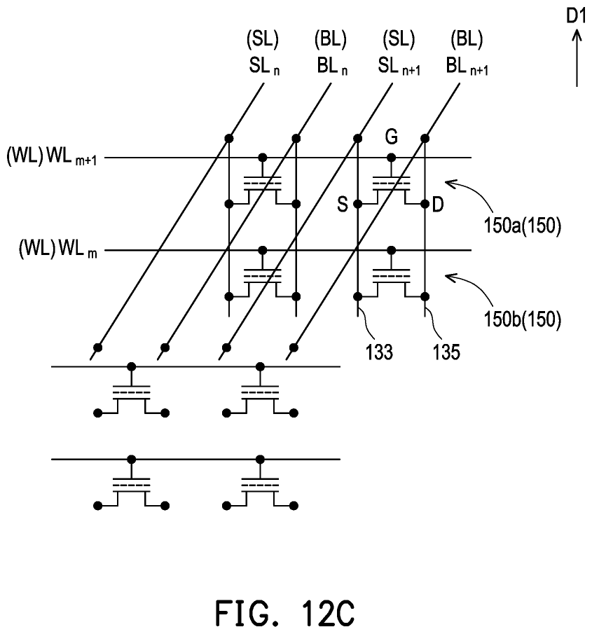

FIG. 12A, FIG. 12B, and FIG. 12C are respectively a schematic perspective view, a schematic plan view, and a schematic circuit diagram of a 3D AND flash memory 1 according to an embodiment of the present invention.

Referring to FIG. 12A, in the present embodiment, the 3D AND flash memory 1 has a plurality of memory cells 150. In detail, as shown in FIG. 12A, a plurality of gate layers 154 are alternately arranged along the vertical direction, and surround the vertical channel pillars 130 respectively. A portion of the vertical channel pillar 130 surrounded by the gate layer 154 may constitute a memory cell 150. In the present embodiment, a single vertical channel pillar 130 may define three memory cells 150 stacked on each other. However, the present invention is not limited thereto. In other embodiments, the number of memory cells 150 may be adjusted according to the number of gate layers 154 in the stack structure 210. Furthermore, the memory cell 150 may be formed at the intersection of the gate layer 154 and the vertical channel pillar 130. Therefore, the greater the number of vertically stacked gate layers 154, the greater the number of memory cells 150 in the memory string. In addition, although only two vertical channel pillars 130 are illustrated in FIG. 12, the present invention is not limited thereto. In alternative embodiments, the 3D AND flash memory 1 may include a plurality of vertical channel pillars 130, and these vertical channel pillars 130 may be arranged in an array in a top view, as shown in FIG. 1B.

In order to operate the 3D AND flash memory 1, after the 3D AND flash memory 1 is manufactured, conductive lines are formed on the 3D AND flash memory 1 to be electrically connected to the 3D AND flash memory 1. In the present embodiment, as shown in FIG. 12A, some conductive lines are formed above the first S/D pillar 133 as the source to serve as the source lines SL, and other conductive lines are formed above the second S/D pillar 135 as the drain to serve as the bit lines BL, and these source lines SL and bit lines BL are arranged in parallel to each other without contacting each other.

An operation of the memory cell 150 in the 3D AND flash memory 1 will be described below.

As shown in FIG. 12B, for the 3D AND flash memory 1, each memory cell 150 may be operated individually. An operation voltage may be applied to the first S/D pillar 133, the second S/D pillar 135 and the corresponding gate layer 154 (which may be regarded as a gate or a word line) of the memory cell 150 for writing (programming) operation, reading operation or erasing operation. When a writing voltage is applied to the first S/D pillar 133 and the second S/D pillar 135, since the first S/D pillar 133 and the second S/D pillar 135 are connected to the channel layer 134, an electron may be transmitted along a first electrical path E1 and a second electrical path E2 (e.g., a double-sided electrical path) and stored in the entire charge storage structure 132.

In addition, referring to FIG. 12C, in the present embodiment, the memory cells 150 may be arranged in a plurality of columns and a plurality of rows to form a 3D AND flash memory array. Each memory cell 150 may include a gate G electrically connected to the word line WL (i.e., WLm, WLm+1), a source S electrically connected to the source line SL (i.e., SLn, SLn+1), and a drain D electrically connected to the bit line BL (i.e., BLn, BLn+1). It should be noted that in the 3D AND flash memory array of the present embodiment, a plurality of memory cells 150 along the extending direction D1 of the S/D pillars 133 and 135 may be connected in parallel with each other. Specifically, as shown in FIG. 12C, the upper memory cell 150a and the lower memory cell 150b share the same source line SLn+1 and the same bit line BLn+1 through the common S/D pillars 133 and 135, and the gate of the upper memory cell 150a is electrically connected to the upper word line WLm+1, and the gate of the lower memory cell 150b is electrically connected to the lower word line WLm. In this case, the architecture and operation method of the 3D AND flash memory array of the present embodiment are different from those of the conventional 3D NAND flash memory array, wherein the conventional 3D NAND flash memory array includes a plurality of memory cells connected in series.

Further, the 3D memory device of FIG. 11 uses the oxide/nitride/oxide first (ONO first) process to form the charge storage structure 132. However, the present invention is not limited thereto. In other embodiments, the ONO last process may also be used to form the charge storage structure. The detail is shown in the following paragraphs.

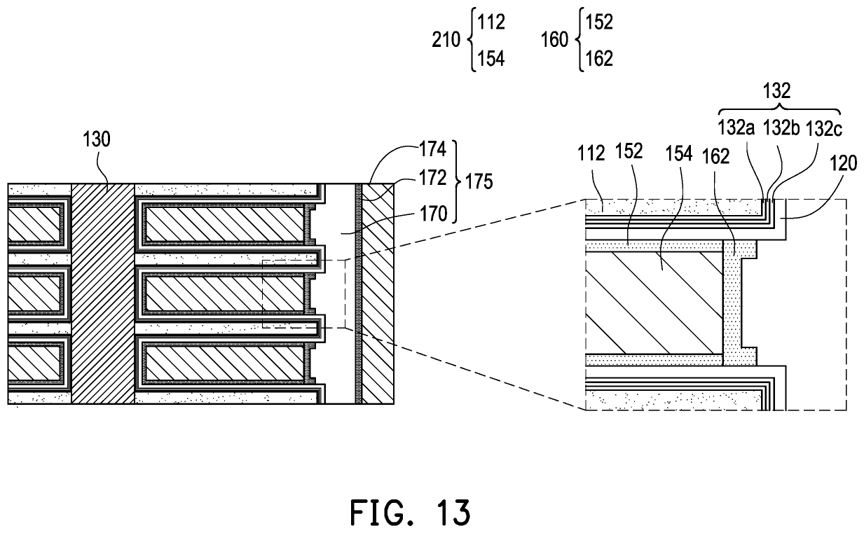

FIG. 13 is a schematic cross-sectional view of a 3D memory device according to alternative embodiments of the invention.

The 3D memory device of FIG. 13 is similar to the 3D memory device of FIG. 11, and the same or similar components are represented by the same or similar reference numbers, which will not be repeated here. The main difference between the above two lies in that the charge storage structure 132 of the 3D memory device illustrated in FIG. 13 is disposed between the buffer layer 120 and the dielectric layer 112, and surrounds the barrier structure 160 and the gate layer 154. That is, the charge storage structure 132 of the 3D memory device illustrated in FIG. 13 is not included in the vertical channel pillar 130.

Specifically, the method of forming the charge storage structure 132 may include: after removing the sacrificial layers 114 in the gate replacement process, forming the charge storage structure 132 to conformally cover the gaps 14; next, sequentially forming the buffer layer 120, the barrier material layer 122, and the conductive material layer 124, as shown in FIG. 6; then, performing a second etching process to remove the barrier material layer 122 and the conductive material layer 124 on the sidewalls of the dielectric layers 112 to expose the buffer layer 120; and forming the barrier layers 162 to cover the sidewalls of the gate layers 154. In this case, as shown in FIG. 13, the charge storage structure 132 may be disposed between the buffer layer 120 and the dielectric layers 112 and surround the barrier structures 160 and the gate layers 154. In the present embodiment, the barrier layers 162 can also effectively block the remaining fluorine in the gate layer 154 from escaping due to the heat treatment process, so as to prevent the oxide layer 170 from being damaged, thereby improving the reliability of the device.

In summary, in the present embodiment, an additional barrier layer is used to cover the sidewall of the gate layer and is connected to the barrier layer surrounding the gate layer, thereby forming a barrier structure that completely wraps all surfaces of the gate layer. Therefore, the barrier structure of the present invention is able to effectively prevent the fluorine outgassing issue from occurring, thereby improving the reliability of the 3D memory device. Further, the forming steps of the barrier structure of the present invention are compatible with the fabrication of current 3D memory device, and can be applied to various 3D memory devices.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A three-dimensional (3D) memory device, comprising:
a substrate;
a stack structure, disposed on the substrate, wherein the stack structure comprises a plurality of dielectric layers and a plurality of gate layers stacked alternately; and
a plurality of barrier structures, respectively wrap a surface of the plurality of gate layers, wherein each barrier structure comprises:
a first barrier layer continuously covering a top surface, a bottom surface and a first sidewall of a corresponding gate layer; and
a second barrier layer covering a second sidewall of the corresponding gate layer opposite to the first sidewall, and connecting the first barrier layer.

2. The 3D memory device according to claim 1, wherein the substrate comprises an array region, and the array region comprises a channel pillar region and a slit region.

3. The 3D memory device according to claim 2, further comprising:
a plurality of vertical channel pillars, penetrating through the stack structure and disposed on the channel pillar region and adjacent to the first sidewall; and
a slit filling structure, penetrating through the stack structure and disposed on the slit region, and adjacent to the second sidewall, wherein the slit filling structure is physically separated from the corresponding gate layer by the second barrier layer.

4. The 3D memory device according to claim 3, wherein the slit filling structure comprises:
an oxide layer, covering a sidewall of the stack structure;
a conductive layer, disposed on the oxide layer; and
a third barrier layer, disposed between the oxide layer and the conductive layer.

5. The 3D memory device according to claim 4, wherein the plurality of gate layers has a width less than a width of the plurality of the dielectric layers, so that the second sidewall and an adjacent dielectric layer jointly form a groove, and the oxide layer partially extends into the groove to connect the second barrier layer.

6. The 3D memory device according to claim 3, further comprising:
a buffer layer, conformally extending between the plurality of dielectric layers and the plurality of gate layers, and between the plurality of vertical channel pillars and the plurality of gate layers.

7. The 3D memory device according to claim 6, wherein the second barrier layer cover the second sidewall and a portion of an adjacent buffer layer, the second barrier layer and the buffer layer jointly form a recess, the recess has a first vertical depth and a second vertical depth, and the first vertical depth is greater than the second vertical depth.

8. The 3D memory device according to claim 6 wherein the first barrier layer is disposed between the buffer layer and the corresponding gate layer.

9. The 3D memory device according to claim 1, wherein each barrier structure completely wraps all surfaces of a corresponding gate layer.

10. The 3D memory device according to claim 1, wherein the 3D memory device comprises: a 3D AND flash memory, a 3D NAND flash memory, a 3D NOR flash memory, or a combination thereof.

11. The 3D memory device according to claim 1, wherein the second barrier layer has a thickness greater than a thickness of the first barrier layer.

12. The 3D memory device according to claim 1, wherein a thickness of the second barrier layer is between 50 Å and 150 Å.

13. A method of forming a three-dimensional (3D) memory device, comprising:
providing a substrate having a first region and a second region;
forming a stack structure having a plurality of dielectric layers and a plurality of sacrificial layers alternately stacked on the substrate;
forming a slit in the stack structure in the second region;
performing a first etching process through the slit to remove the plurality of sacrificial layers to form a plurality of gaps between the plurality of dielectric layers;
forming a plurality of gate layers and a plurality of first barrier layers in the plurality of gaps, wherein the plurality of first barrier layers surround a portion of a surface of the plurality of gate layers and expose a sidewall of the plurality of gate layers; and
forming a plurality of second barrier layers to cover the sidewall of the plurality of gate layers, wherein the plurality of second barrier layers are respectively connected to the plurality of first barrier layers to form a plurality of barrier structures.

14. The method according to claim 13, wherein after forming the plurality of second barrier layers, the method further comprises forming a slit filling structure in the slit.

15. The method according to claim 13, wherein before forming the slit, the method further comprises forming a plurality of vertical channel pillars in the stack structure in the first region.

16. The method according to claim 13, wherein the forming the plurality of gate layers and the plurality of first barrier layers in the plurality of gaps comprises:
forming a first barrier material layer and a conductive material layer to fill in the plurality of gaps; and
performing a second etching process to remove the first barrier material layer and the conductive material layer on a sidewall of the plurality of dielectric layers to form the plurality of gate layers and the plurality of first barrier layers in the plurality of gaps.

17. The method according to claim 16, wherein a material of the first barrier material layer comprises titanium (Ti), titanium nitride (TiN), tantalum (Ta), tantalum nitride (TaN), or a combination thereof.

18. The method according to claim 16, wherein after performing the second etching process, the sidewall of the plurality of gate layers is concave from the sidewall of the plurality of the dielectric layers to form a plurality of grooves.

19. The method according to claim 18, wherein the forming the plurality of second barrier layers comprises:
forming a second barrier material layer to conformally cover the sidewall of the plurality of the dielectric layers and a surface of the plurality of grooves; and
performing a third etching process to remove the second barrier material on the sidewall of the plurality of the dielectric layers to form the plurality of second barrier layers in the plurality of grooves, wherein each second barrier layer is formed into a C-shaped structure.

20. The method according to claim 19, wherein the first barrier material layer and the second barrier material layer have the same material.
